(19) United States
(12) Patent Application Publication
(10) Pub. No.: US 2004/0136473 A1
(43) Pub. Date: Jul. 15, 2004

(54) Digital receiver

(76) Inventors: Chun Hua Yang, Singapore (SG); Theng Tee Yeo, Singapore (SG); Tomisawa Masayuki, Singapore (SG)

Correspondence Address: QUARLES & BRADY LLP, 411 E. WISCONSIN AVENUE, SUITE 2040, MILWAUKEE, WI, 53202-4497, US

(21) Appl. No.: 10/727,855

(22) Filed: Dec. 4, 2003

(30) Foreign Application Priority Data
Dec. 5, 2002 (SG) 200207436-7

(51) Int. Cl. H03D 3/00; H03K 9/06

(52) U.S. Cl. 375/322

(57) ABSTRACT

A digital receiver, comprising: a frequency converter (100, 101, 102, 103, 104, 105) arranged to convert a received signal into baseband signals; delay units (106, 107) arranged to delay the baseband signals to provide delayed signals; normalizing means (108) arranged to truncate the baseband signals and the delayed signals to a predetermined length and provide normalized signals; a demodulator (109) arranged to demodulate the normalized signals and provide a demodulated signal; and frequency offset sensing means (110) arranged to sense an envelope of the demodulated signal to provide an offset signal indicative of a frequency offset of the received signal.

### FIELD OF THE INVENTION

The present invention relates to a digital receiver suitable for use in a Burst-mode communication system.

### BACKGROUND OF THE INVENTION

Low power consumption, cost-reduction, and compact size are some of the key features of a mobile/personal communication system such as GSM, DECT and Bluetooth based systems. Full integration is a very important way to reduce cost and size. The zero-IF receiver can be implemented in a highly integrated way. However, it suffers from dc offset, self-mixing, and mismatch between the different downconversion paths. The use of zero-IF is limited due to its poor performance. Although the conventional IF (heterodyne) receiver can achieve good performance, its implementation needs many off-chip components, which makes it vulnerable, expensive, and sensitive to external parasitic signals. Its power consumption is also increased. Accordingly, a need exists in the art to provide a digital receiver which can be implemented in a highly integrated way while still maintaining high quality signal reception.

### SUMMARY OF THE INVENTION

In accordance with one aspect of the present invention, there is provided a digital receiver, comprising: a frequency converter arranged to convert a received signal into baseband signals; delay units arranged to delay the baseband signals to provide delayed signals; normalizing means arranged to truncate the baseband signals and the delayed signals to a predetermined length and provide normalized signals; a demodulator arranged to demodulate the normalized signals and provide a demodulated signal; and frequency offset sensing means arranged to sense an envelope of the demodulated signal to provide an envelope signal.

Typically, the normalizing means is arranged to truncate the baseband signals and the delayed signals by: selecting from the baseband signals and the delayed signals one with the largest absolute value; determining a bit position of most significant bit of the selected signal; truncating each of the signals to the pre-determined length dependent upon the bit position.

Typically, the frequency offset sensing means comprises: means arranged to track the envelop of the demodulated signal to provide a tracking signal; and filter arranged to low pass filter the tracking signal to provide the envelope signal.

An advantage of the present invention is to provide a digital receiver suitable to be implemented in the form of an application specific integrated circuit (ASIC) with the specific design features of low power consumption and small size.

Another advantage of the present invention is to provide a simple normalization scheme to truncate a signal without introducing unacceptable distortion.

Still another advantage of the present invention to provide a method and apparatus arranged to estimate and compensate effects of the frequency offset between the transmitter and receiver in the system.

### BRIEF DESCRIPTION OF THE DRAWINGS

Embodiments of the invention will now be discussed, by way of example, with reference to the accompanying drawings in which like reference characters identify correspondingly throughout and wherein:

FIG. 1 schematically illustrates a first embodiment of a digital receiver according to the present invention;

FIG. 2 schematically illustrates the structure of an analog front-end of the digital receiver shown in FIG. 1;

FIG. 3 shows an example of the operation of a normalizer of the digital receiver of FIG. 1;

FIG. 4 is a schematic block diagram illustrating the structure of a demodulator of the digital receiver shown in FIG. 1;

FIG. 5 is a schematic block diagram illustrating the structure of a filtering device of the digital receiver shown in FIG. 1;

FIG. 6 is a flow chart of the algorithm for computing the low frequency component caused by the frequency offset in the filtering device of FIG. 5;

FIG. 7 schematically illustrates a second embodiment of a digital receiver according to the present invention;

FIG. 8 is a schematic block diagram illustrating the structure of a demodulator of the digital receiver shown in FIG. 7;

FIG. 9 is a schematic block diagram illustrating the structure of a filtering device of the digital receiver shown in FIG. 7; and

FIG. 10 is a flow chart of the algorithm for computing the low frequency component caused by the frequency offset in the filtering device of FIG. 9.

### DETAILED DESCRIPTION OF THE PREFERRED EMBODIMENTS OF THE INVENTION

A first embodiment of a digital receiver for a burst-mode communication system is shown in FIG. 1. The receiver 1 includes an analogue front-end 100 arranged to convert a RF signal received from an antenna into a low IF signal; an AD converter 101 arranged to provide analogue-to-digital conversion of the output from the analogue front-end 100; a pair of mixers 102 and 103, coupled to the output of the AD converter 101, arranged to mix the AD converted signal with sine and cosine signals respectively to obtain two orthogonal components of the low IF signal, namely, I′ₙ and Q′ₙ; a pair of low pass filter (LPF) 104 and 105, coupled to the pair of mixers, arranged to filter high frequency contents of the two orthogonal components to obtain two baseband orthogonal components, namely, Iₙ and Qₙ; a pair of delay units 106 and 107, coupled to the pair of LPF 104 and 105, arranged to delay the two baseband orthogonal components Iₙ and Qₙ by a sampling period, Tₛ, to obtain two delayed components Iₙ₋₁ and Qₙ₋₁; a normalizer 108, coupled to the outputs of the pair of LPF 104 and 105, as well as the outputs of the pair of delay units 106 and 107, arranged to normalize the four components (i.e., Iₙ, Qₙ, Iₙ₋₁ and Qₙ₋₁) by truncating them to pre-determined lengths of L bits, to yield four normalized signals, Iₙ^{tr}, Iₙ₋₁^{tr}, Qₙ^{tr} and Qₙ₋₁^{tr}; demodulator 109 arranged to demodulate the normalized signals from the normalizer 108; a filtering device 110 arranged to low frequency filter the demodulated signal xₙ so as to obtain its average value dcₙ; a decider 111 arranged to decide a tentative signal \hat{b}ₙ according to the demodulated signal xₙ and the average value dcₙ; and a symbol timing recovery 112 arranged to recover the symbol timing of the tentative signal \hat{b}ₙ.

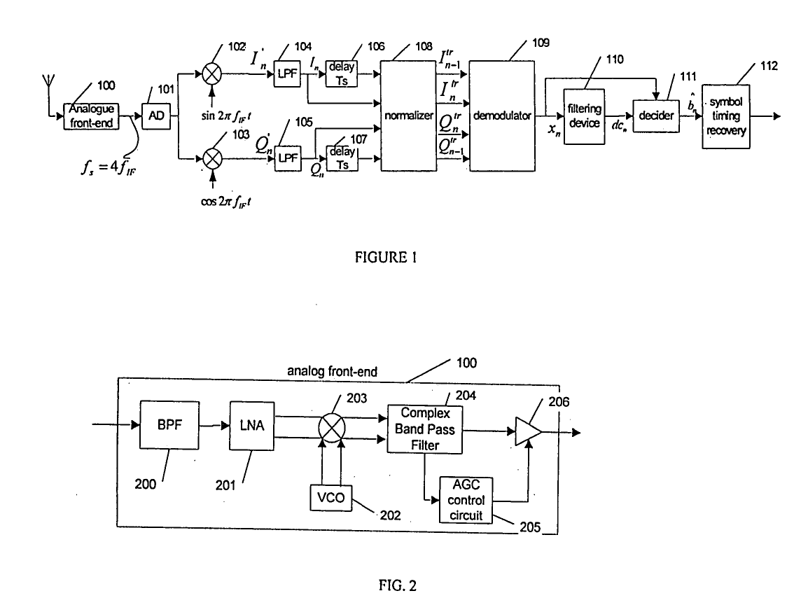

Hereinafter, with reference to FIGS. 2-6, the operations of the analog front-end 100, normalizer 108, demodulator 109, filtering device 110 will be explained.

FIG. 2 schematically illustrates the structure of the analog front-end 100 of the digital receiver 1 shown in FIG. 1. The analog front-end 100 includes a band-pass filter 200 arranged to filter the signal received from the antenna; a low noise amplifier 201, covering the whole bandwidth of the receiver 1, arranged to provide low noise amplification of the band-pass filtered signal from BPF 200 to suppress out-of block parts of the received signal; a voltage controlled oscillator 202 arranged to generate a local oscillating signal; a mixer 203 arranged to mix the amplified signal from LNA 201 with the local oscillating signal from VCO 202 to downconvert the frequency of the received signal into a low intermediate frequency (IF); a complex band-pass filter 204, centered at f_{IF}, arranged to band-pass filter the signal from the mixer to suppress its mirror signal; an AGC control circuit 205 arranged to detect the strength of the filtered signal from the complex band-pass filter 204 and control a gain of the following amplifier 206; an amplifier 206 arranged to amplify the filtered signal from the complex band-pass filter 204 under the gain-control of AGC 205. The above-described analog front end 100 functions to convert the frequency of the received signal from the antenna from a radio frequency into a low intermediate frequency. A low intermediate frequency is an intermediate frequency lower than a conventional intermediate frequency. A low-IF receiver, like a zero-IF receiver, has a multi-path topology suitable for a highly integrated design to reduce cost and size. It uses an IF frequency of a few hundred kilohertz and is insensitive to parasitic baseband signals, such as dc offset and self-mixing products. The low-IF receiver combines the advantages of both the conventional IF and the zero-IF receivers. It also has a high performance and is highly integrable. Moreover, due to use of the complex bandpass filter 204, following the analog front-end 100, only one AD converter is needed for analog-digital conversion of the low IF signal into a digital signal rₙ at a fixed sampling frequency fₛ. The output signal rₙ, from the AD converter is represented as:

rₙ=A cos [2π(f_{IF +Δ}_{f})nTₛ+φₙ+θ]+nₙ, (1)

where, A is the amplitude of the digital signal, Δ_{f} is the frequency offset between the transmitter and receiver in the system, which is caused by the discrepancy between the oscillators at the transmitter and receiver or the Doppler effect, θ is the phase offset introduced by the VCO of the receiver, nₙ and φₙ are the nth samples of white Gaussian noise and the phase of GFSK modulated signal respectively.

The low IF signal from the AD 101 is further downconverted into a basedband signal by the pairs of mixers (102, 103) and low pass filters (104 and 105). In the mixers 102 and 103, the digital signals from AD 101 are mixed with sine and cosine signals, sin 2πf_{IF}t and cos 2πf_{IF}t, respectively, to obtain two orthogonal components, I′ₙ and Q′ₙ. After filtering high frequency terms of the two orthogonal components by the pair of LPFs 104 and 105, two orthogonal baseband components (i.e., in-phase and quadrature base band components Iₙ and Qₙ) are produced as follows:

Iₙ=−A sin [2πΔ_{f}nTₛ+φ(nTₛ)+θ] Qₙ=A cos [2πΔ_{f}nTₛ+φ(nTₛ)+θ] (2)

If fₛ=4f_{IF}, then the above sine and cosine signals can be simplified as bit sequences 0,1,0,1 and 1,0,−1,0. This technique greatly simplifies the design for the mixers, since the mixing of the digital signal from AD 101 with the two bit sequences needn't be implemented by multipliers.

At the receiver side, the amplitude of its output signal depends on the transmitted signal power, the propagation loss, the fading environment and the AGC. Therefore, the output from the digital receiver may have many bits and the valid signal range may vary due to the aforementioned factors. To minimize the logic size and power consumption of the receiver, before passing the four components, Iₙ, Qₙ from the pair of LPFs and Iₙ₋₁, Qₙ₋₁ from the pair of delay units, to the demodulator 109 for further processing, a simple normalizer 108 is adopted to automatically truncate the lengths of these components from N bits to L bits (L<N). L is experimentally determined so that the truncation of signals will not degrade the performance of the receiving system.

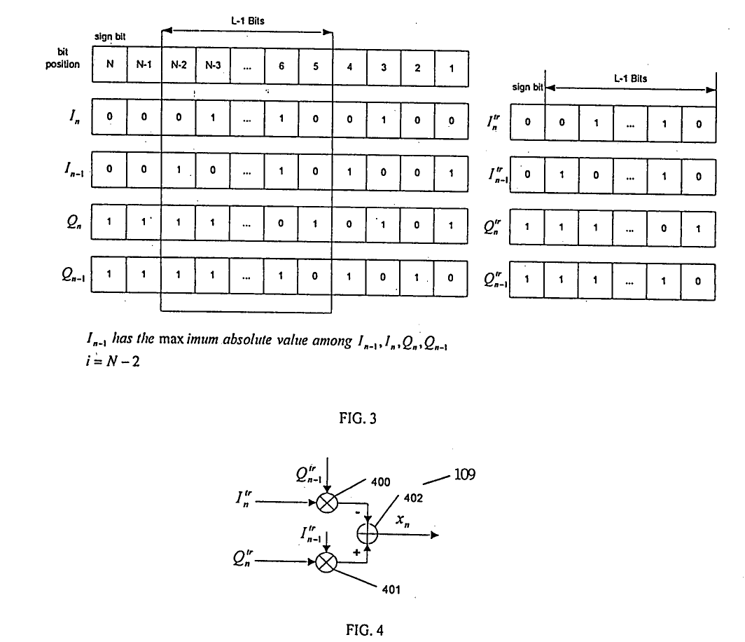

Referring FIG. 3, an example of the operation of the normalizer 108 is discussed in detail. It is assumed that the lengths of the four components (Iₙ, Iₙ₋₁, Qₙ, Qₙ₋₁) input into the normalizer are N bits and the lengths of the outputs from the normalizer are L bits. The four components (Iₙ, Iₙ₋₁, Qₙ, Qₙ₋₁) are signed data. The normalization procedure comprises the following steps:

Find the input with the maximum absolute value from the four input components. In this example, the input with the maximum absolute value is Iₙ₋₁.

Determine the bit position of the most significant bit of the input component having the maximum absolute value. Most significant bit means a bit which makes the largest contribution to the absolute value of binary data. If the binary data is a signed data, the most significant bit is the first bit whose value is different from that of its sign bit. For Iₙ₋₁, since the value of its sign bit is ‘0’, most significant bit thereof shall be the first bit whose value is ‘1’. From FIG. 3, it can be seen that the bit position of most significant bit of Iₙ₋₁ is N-2, and is recorded as i (i=N-2).

Truncate each of the inputs to a pre-determined length of L bits. In this example, since the four inputs are signed data, their sign bits remain in their truncated signals. More particularly, the four inputs are truncated by selecting L-1 bits of each input starting from the bit position determined in the above step, i.e., L-1 bits between the i th and (i-L-2) th bits, and then adding a sign bit of each of the inputs. In the example shown in FIG. 3, the four inputs are truncated by selecting L-1 bits from the (N-2) th bit to the (N-L-4) th bit (i.e., the fifth bit) and adding the sign bit of each input (i.e., sign bits 0, 0, 1 and 1) as a first bit of each truncated signal. The four truncated signals Iₙ, Iₙ₋₁, Qₙ, Qₙ₋₁ with the pre-determined length of L bits are shown on the right side of FIG. 3.

The truncated data Iₙ^{tr}, Iₙ₋₁^{tr}, Qₙ^{tr}, Qₙ₋₁^{tr} is inputted to the demodulator 109 as depicted in FIG. 4. The demodulator 109 comprises a pair of multipliers 400 and 401 to cross multiple the four truncated inputs by multiplying Iₙ^{tr}, by Qₙ₋₁^{tr} and Qₙ^{tr} by Iₙ₋₁^{tr}. The demodulator 109 also includes an adder 402 arranged to add the outputs from the multipliers. After summing by the adder, The demodulator output is:

xₙ=Qₙ^{tr}Iₙ₋₁^{tr}−Qₙ₋₁^{tr}Iₙ^{tr}=A² sin(2πΔ_{f}Tₛ+Δφ). (3)

where,

$${T}_{s} = \frac{{T}_{b}}{K}$$

is the sampling duration, Δφ=φ((nTₛ)−φ((n−1)Tₛ) represents the phase difference during a sampling period. The presence of frequency offset, Δ_{f}, degrades the overall system performance. Under ideal conditions, the frequency offset Δ_{f}=0, the expectation value of the demodulator output is A² sin Δφ. However, in practice, the frequency offset Δ_{f} is always non-zero. From Eqn(3), it can be seen that the demodulator output xₙ has been distorted by the frequency offset. When 2πΔ_{f}Tₛ is small, the expression of Eqn(3) can be approximated by:

xₙ≈A²(2πΔ_{f}T_{S} cos Δφ+sin Δφ) (4)

The expectation value of xₙ in Eqn(4) is:

E[xₙ]=A²(2πΔ_{f}T_{S}E[cos Δφ]+E[sin Δφ]) (5)

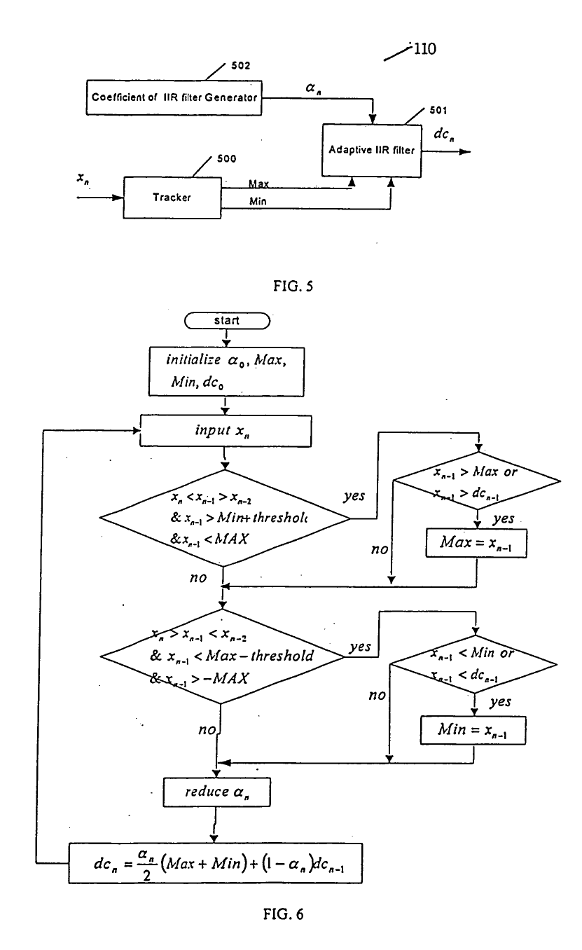

Under the assumption of equally distributed input data, it can be seen that E[sin Δφ]=0. From Eqn(5), the frequency offset produces a low frequency signal A² 2πΔ_{f}Tₛ cos Δφ at the output of the demodulator 109. A reference signal for the following decider 111 needs to be non-zero to compensate the frequency offset. A filtering device 110, a block diagram of the structure and a flow chart of the operation of which are respectively depicted in FIGS. 5 and 6, provides a mechanism for tracking and filtering the low frequency signal caused by the frequency offset.

In the prior art, such as U.S. Pat. No. 5,448,594, entitled “One-bit Differential Demodulator”, a low pass filter is designed to track the low frequency signal A²2πΔ_{f}Tₛ cos Δφ directly. The disadvantage of this method is that if the bandwidth of the filter is excessive, the resultant output will contain too much high frequency content, which endangers the proper operation of the differential detector. If the bandwidth of the filter is insufficient, a long time is needed to capture the burst data. Instead of tracking the low frequency component directly, in the present invention, the envelope of the demodulator output xₙ is tracked and low-pass filtered to obtain the low frequency component. As the envelope of the demodulated signal tends to be more stable than the demodulated signal itself, a LPF with a much wider bandwidth can be employed to give a fast tracking without introducing too much disturbance. A separate feature which allows a further improvement in performance, i.e., capture of the data in a shorter time while keeping a good BER performance simultaneously, is the use of an adaptive low pass filter. During the beginning of the data reception, the filter can be allowed to begin operation at a wider bandwidth. This is useful in terms of capturing the burst data quickly. As more data is received, the bandwidth of the filter is reduced gradually in order to suppress the high frequency components.

The filtering device of the present invention is composed of three main functional blocks: a tracker 500, an adaptive IIR filter 501 and a coefficient of Adaptive IIR filter generator 502. Referring FIG. 6, at the beginning of the loop, the parameters α, Max, Min and dc are preset to an appropriate value (e.g., zero), in which parameter α is a coefficient of the IIR filter 501, Max and Min are respectively the values of positive and negative peaks of the envelope of the demodulator output xₙ, and dc is the output of the IIR filter 501, i.e., low frequency component of the envelope of the demodulator output xₙ. The values of the positive and negative peaks Max, Min of the input signal xₙ are updated by using tracker 500 based on the following rules:

if xₙ<xₙ₋₁>xₙ₋₂ and xₙ₋₁>Min+threshold and xₙ₋₁<MAX, And if xₙ₋₁>Max or xₙ₋₁>dcₙ₋₁, then Max=xₙ₋₁

if xₙ>xₙ₋₁<xₙ₋₂and xₙ₋₁<Max−threshold and xₙ₋₁>−MAX, And if xₙ₋₁<Min or xₙ₋₁<dcₙ₋₁, then Min=xₙ₋₁

where, xₙ, xₙ₋₁, xₙ₋₂ are samples of the demodulator output at time n, time n-1 and time n-2, respectively. The parameter “threshold” is a user-defined constant reflecting the smallest gap between the positive and negative peaks. The parameter “MAX” is also a user-defined constant, wherein the tracked positive and negative peaks are confined within the range (−MAX, MAX). Moreover, “threshod” and “MAX” are proportional to the sampling duration, the modulation index being employed, as well as the amplitude of the input signal. Coefficient of adaptive IIR filter generator 502 adjusts the coefficient αₙ of the IIR filter 501 at time n to reduce the bandwidth of the adaptive IIR filter. The coefficient αₙ at time n is reduced as a function of time, for example,

$${α}_{n} = \frac{31}{32} {α}_{n - 1} + \frac{1}{32} * \frac{1}{256} .$$

The maximum and the minimum values Max,Min and the parameter αₙ are used as the inputs to the adaptive IIR filter 501 for the calculation of the low frequency component of the envelope of the demodulator output xₙ according to the following equation

$$d {c}_{n} = ( 1 - {α}_{n} ) d {c}_{n - 1} + \frac{{α}_{n}}{2} ( Max + Min ) \qquad ( 6 )$$

where, dcₙ is the low frequency component of the envelope of the signal xₙ at time n, dcₙ₋₁ is the low frequency component of the envelope of the signal xₙ₋₁ at time n-1, αₙ is the filter coefficient at time n.

The above process is repeated as long as the communication device is in operation. The signal dcₙ is used as an input to a decider 111 of FIG. 1 as a reference signal. The decider 111 makes a hard decision or soft decision to yield a tentative signal \hat{b}ₙ. For a hard decision, the decider 111 can be a comparator which makes decision according to the following rule:

$${\hat{b}}_{n} = \{ \begin{matrix}1 , & {x}_{n} > d {c}_{n} \\ 0 , & {x}_{n} \leq d {c}_{n}\end{matrix}$$

However, for a soft decision, the decider 111 can be a subtractor, which subtracts the output of the filtering device, dcₙ, from that of the demodulator 109, xₙ, and a comparator, which makes decision according to the following rule:

$${\hat{b}}_{n} = \{ \begin{matrix}1 , & {x}_{n} - d {c}_{n} > 0 \\ 0 , & {x}_{n} - d {c}_{n} \leq 0\end{matrix}$$

Based on the filtering device, the effect of frequency offset can be estimated without using a frequency detector or a complex feedback loop. The symbol timing of the tentative signals \hat{b}ₙ is recovered by the symbol timing recovery unit 112. Since all the values after the AD converter are fixed-point data, all calculations can be implemented by simple logical operations such as shifting, addition, subtraction, XOR and so on. At the same time, the low-IF topology can be implemented with a high degree of integration and a high performance.

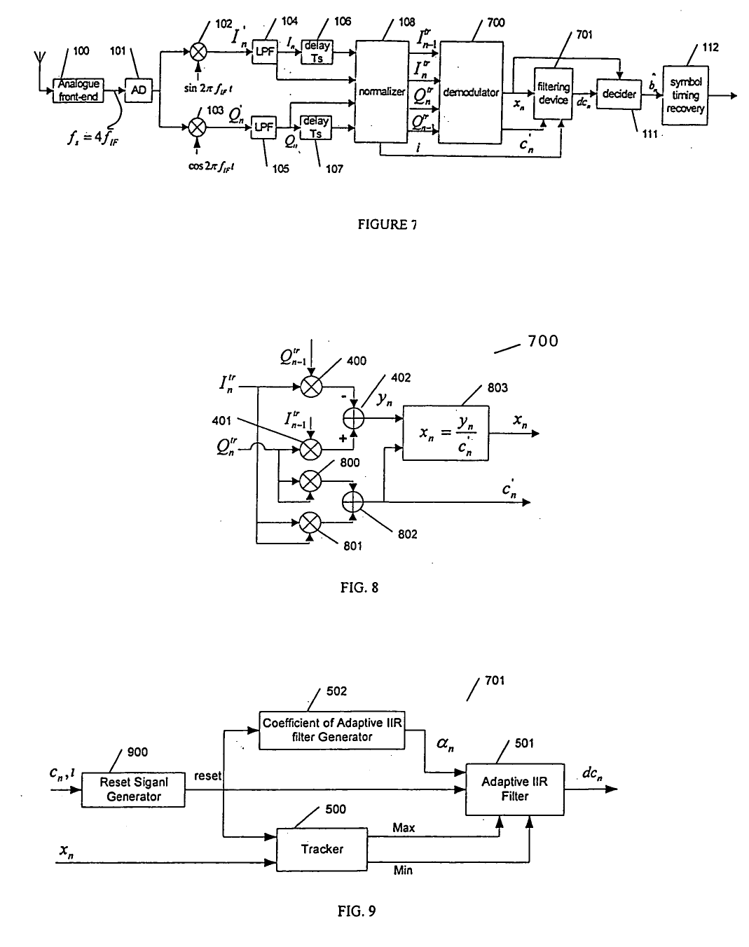

With reference to FIGS. 7-10, a second embodiment of a digital receiver of the present invention will be explained.

Referring first to FIG. 7, a digital receiver 2 of the second embodiment includes an analogue front-end 100, an AD converter 101, a pair of mixers 102 and 103, a pair of LPFs 104 and 105, a pair of delay units 106 and 107, a normalizer 108, a demodulator 700, a filtering device 701, a decider 111, and a symbol timing recovery 112. It can be seen that the differences between the digital receiver 1 of FIG. 1 and the digital receiver 2 of FIG. 7 lie in the structures of their demodulators and their filtering devices.

FIG. 8 is a schematic block diagram illustrating the structure of the demodulator 700 of the digital receiver 2 shown in FIG. 7. Comparing this demodulator 700 with the demodulator 109 of the digital receiver 1, the demodulator 700 of the receiver 2 further comprises means arranged to normalize the sum from the adder 402 to its signal power, including a pair of multipliers 800 and 801 arranged to self-multiply the two component Iₙ and Qₙ, an adder 802 arranged to sum the outputs from the pair of multipliers, and a divider 803 arranged to divide the sum (Qₙ^{tr} Iₙ₋₁^{tr} −Qₙ^{tr} Iₙ^{tr}) from the adder 402 with the sum (c′ₙ=(Iₙ^{tr})²+(Qₙ^{tr})²) from the adder 802, yielding:

$${x}_{n} = \frac{{Q}_{n}^{tr} {I}_{n - 1}^{tr} - {Q}_{n - 1}^{tr} {I}_{n}^{tr}}{{( {I}_{n}^{tr} )}^{2} + {( {Q}_{n}^{tr} )}^{2}} = sin ( 2 {πΔ}_{f} {T}_{S} + Δ Φ ) \qquad ( 7 )$$

The sine of the change in phase of the received signal r(t) is obtained and is independent of the signal power. When 2πΔ_{f}Tₛ is small, the expression of Eqn(7) can be approximated by:

xₙ≈2πΔ_{f}T_{S} cos Δφ+sin Δφ (8)

The expectation value of xₙ in Eqn(8) yields:

E[xₙ]=2πΔ_{f}T_{S}E[cos Δφ]+E[sin Δφ] (9)

For the reason given in the first embodiment, E[sin Δφ]=0. From Eqn(9), the frequency offset produces a low frequency signal 2πΔ_{f}T_{S} cos Δφ at the output of the demodulator 700. The reference signal for the decider 111 is non-zero due to the frequency offset. A filtering device 701 is added in FIG. 7 to adaptively track the low frequency signal 2πΔ_{f}T_{S} cos Δφ, which is used as the reference signal for the following decider 111. The detailed structure of the filtering device 701 is shown in FIG. 9. The difference between the filtering devices of FIGS. 5 and 9 is that the filtering device 701 further comprises a reset signal generator 900 which is used to detect the start of data transmission and generate a reset signal to initiate the tracker 500, the adaptive IIR filter 501, and the coefficient of adaptive IIR filter generator 502, because in order to allow the receiver to operate properly in a burst mode communication system, it is important to determine when the burst data transmission starts. The inputs to the demodulator 700 are truncated signals, which makes the sum c′ₙ unable to accurately represent the signal power of the received signal. To correct this problem, before detecting the start of the burst data transmission, the reset signal generator 701 eliminates the effect of the normalizer on the signal power c′ₙ by shifting it according to the bit position i from the normalizer 108. In this embodiment, the reset signal generator 900 right-shifts the signal power c′ₙ with 2(N-i-1) bits. It is apparent to an ordinary person skilled in the art that other methods can be applied to eliminate the effect of the normalization, which falls within the protective scope claimed by this application. The reset signal generator 900 further includes a simple LPF filter which is used to calculate the average value of the de-normalized signal, namely, the signal power cₙ.

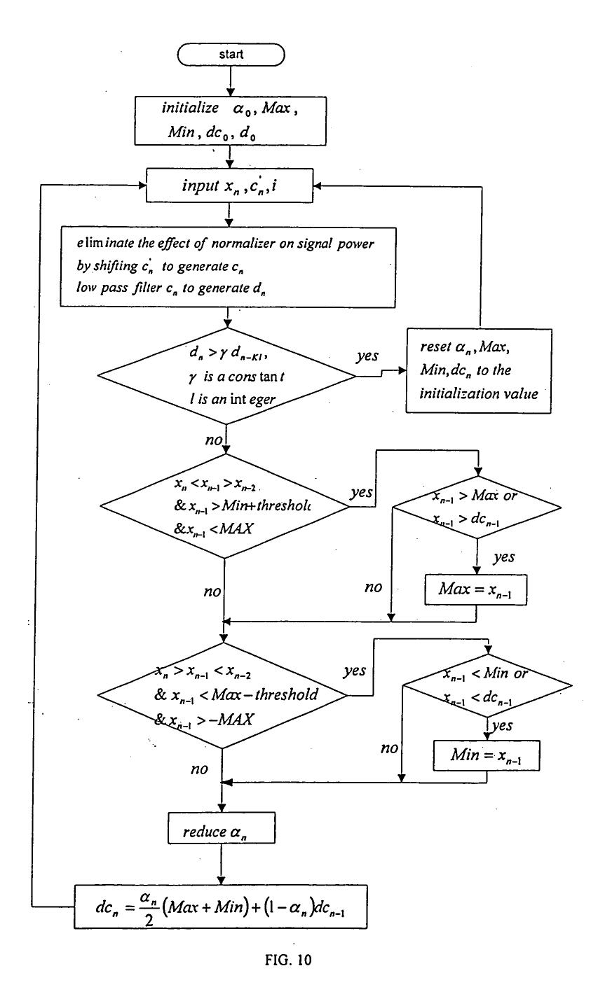

FIG. 10 shows the flow chart of the operation of the filtering device 701 of FIG. 9. Prior to the start of data transmission, the parameters α, Max, Min, dc and d should be reset to the pre-defined initialization values, in which parameter d is the output of the simple LPF filter of the reset signal generator 900. Then, the signal power c′ₙ from the demodulator 700 is de-normalized according to the bit position from the normalizer 108 and low-pass filtered by the reset signal generator 900 with the form dₙ=σdₙ₋₁+(1−σ)cₙ, where σ is a constant in the range of (0,1), to obtain an average value of the signal power cₙ. The average value dₙ of the signal power cₙ is compared with its previous value dₙ₋₁ at the symbol rate to determine the start of the data transmission. In this embodiment, the average value dₙ is compared with its weighted previous values γdₙ₋ₖₗ, in which γ represents a weighting factor of dₙ₋ₖₗ, K is the oversampling factor which is defined in Eqn.(3) and I is an integer (I=1,2,3 . . . ).

Then, the positive and negative peaks of the demodulator output xₙ are tracked by tracker 500 based on the following rules:

if xₙ<xₙ₋₁>xₙ₋₂ and xₙ₋₁>Min+threshold and xₙ₋₁<MAX, And if xₙ₋₁>Max or xₙ₋₁>dcₙ₋₁, then Max=xₙ₋₁

if xₙ>xₙ₋₁<xₙ₋₂ and xₙ₋₁<Max−threshold and xₙ₋₁>−MAX, And if xₙ₋₁<Min or xₙ₋₁<dcₙ₋₁, then Min=xₙ₋₁

Since the amplitude of the input signal to the demodulator 700 of FIG. 8 is normalized, the two pre-determined constants “threshold” and “MAX” are only proportional to the sampling duration, the modulation index being employed. The maximum and the minimum values Max,Min are used as the inputs to the adaptive IIR filter 501 for the calculation of the low frequency component according to the following equation

$$d {c}_{n} = ( 1 - {α}_{n} ) d {c}_{n - 1} + \frac{{α}_{n}}{2} ( Max + Min ) . \qquad ( 10 )$$

The bandwidth of the adaptive IIR filter is reduced gradually by adjusting the coefficient αₙ in the coefficient of adaptive IIR filter generator 502. The coefficient αₙ is reduced as a function of time, for example,

$${α}_{n} = \frac{31}{32} {α}_{n - 1} + \frac{1}{32} * \frac{1}{256} .$$

The above process is repeated as long as the communication device is in operation. The signal dcₙ is used as an input to a decider 111 of FIG. 7 as a reference signal. The decider 111 makes a hard decision or soft decision to yield a tentative signal \hat{b}ₙ. For a hard decision, the decider 111 can be a comparator which makes decision according to the following rule:

$${\hat{b}}_{n} = \{ \begin{matrix}1 , & {x}_{n} > d {c}_{n} \\ 0 , & {x}_{n} \leq d {c}_{n}\end{matrix}$$

However, for a soft decision, the decider 111 can be a subtractor, which subtracts the output of the filtering device, dcₙ, from that of the demodulator 109, xₙ, and a comparator, which makes decision according to the following rule:

$${\hat{b}}_{n} = \{ \begin{matrix}1 , & {x}_{n} - d {c}_{n} > 0 \\ 0 , & {x}_{n} - d {c}_{n} \leq 0\end{matrix}$$

Based on the filter device, the effect of frequency offset can be estimated without using frequency detector and complex feedback loop. The symbol timing of the tentative signals \hat{b}ₙ is recovered by the symbol timing recovery unit 112.

In conclusion, a single-chip digital receiver for a burst mode communication system has been disclosed. The digital receiver of the present invention is suitable for implementation as an ASIC and is insensitive to frequency offset. The invention should not be restricted to the present form. For example, although in the disclosure of the present invention the decider is shown to directly follow the filtering device, it can be modified to follow other elements, such as a phase offset compensator which is arranged to compensate the phase offset existing in the signals output from the filtering device. Numerous modifications, changes, variations, substitutions and equivalents will occur to those skills in the art without departing from the spirit and scope of the present invention as defined by the following claims:

1. A digital receiver, comprising:
a frequency converter arranged to convert a received signal into baseband signals;
delay units arranged to delay the baseband signals to provide delayed signals;
normalizing means arranged to truncate the baseband signals and the delayed signals to a predetermined length and provide normalized signals;
a demodulator arranged to demodulate the normalized signals and provide a demodulated signal; and
frequency offset sensing means arranged to sense an envelope of the demodulated signal to provide an offset signal indicative of a frequency offset of the received signal.

2. A digital receiver according to claim 1, wherein the normalizing means is arranged to truncate the baseband signals and the delayed signals by:
finding a signal with the largest absolute value among the baseband signals and the delayed signals;
determining a bit position of most significant bit of the signal; and
truncating each of the baseband signals and the delayed signals to the pre-determined length dependent upon the bit position.

3. A digital receiver according to claim 2, wherein the baseband signals and the delayed signals are signed signals.

4. A digital receiver according to claim 3, wherein each of the normalized signals include a sign bit of each of the baseband signals and the delayed signals.

5. A digital receiver according to claim 2, wherein the pre-determined length is so determined that the normalized signals do not degrade the performance of the receiver.

6. A digital receiver according to claim 1, wherein the frequency offset sensing means comprises:
means arranged to track the envelope of the demodulated signal to provide an envelope signal; and
filter arranged to low pass filter the envelope signal to provide the offset signal.

7. A digital receiver according to claim 6, wherein the filter is an adaptive IIR filter.

8. A digital receiver according to claim 6, wherein the sensing means further comprises a filter coefficient generator arranged to generate and adjust the coefficient of the filter.

9. A digital receiver according to claim 8, wherein the filter coefficient generator reduces the filter coefficient as a function of time.

10. A digital receiver according to claim 9, wherein the filter coefficient generator adjusts the filter coefficient according to the following:
$${α}_{n} = \frac{31}{32} {α}_{n - 1} + \frac{1}{32} * \frac{1}{256} ,$$
wherein an is the filter coefficient at time n, αₙ₋₁ is the filter coefficient at time n-1.

11. A digital receiver according to claim 1, wherein the demodulator further comprises a power normalizing means arranged to generate a power signal from the normalized signals and provide a normalized demodulated signal to the sensing means.

12. A digital receiver according to claim 11, wherein the sensing means further comprises:
a reset signal generator for detecting the start of input data transmission and reset the sensing means.

13. A digital receiver according to claim 12, wherein the reset signal generator is arranged to detect the power signal to detect the start of transmission.

14. A digital receiver according to claim 12, wherein the reset signal generator further de-normalize the power signal dependent upon the bit position from the normalizing means.

15. A digital receiver according to claim 1, wherein the frequency converter comprises:
an analogue front-end arranged to convert a frequency of the received signal from a radio frequency into a low intermediate frequency to provide a low intermediate frequency signal.

16. A digital receiver according to claim 15, wherein the frequency converter further comprises:
an analogue-digital converter arranged to analogue-to-digital convert the low intermediate frequency signal to provide a digital signal;
mixers arranged to respectively mix the digital signal respectively with sine and cosine signals to obtain two orthogonal components; and
filters arranged to filter high frequency parts of the two orthogonal components to obtain the baseband signals.

17. A digital receiver according to claim 1, further comprising:
deciding means arranged to decide a tentative signal from the demodulated signal and the offset signal.

18. A digital receiver according to claim 17, wherein the deciding means comprises a comparator arranged to compare the demodulated signal with the offset signal to provide the tentative signal.

19. A digital receiver according to claim 17, wherein the deciding means comprises:
a subtractor arranged to subtract the offset signal from the demodulated signal and provide a difference signal; and
a comparator arranged to compare the difference signal with zero to provide the tentative signal.

20. A digital receiver according to claim 17, further comprising a symbol timing recovery arranged to a symbol timing of the tentative signal.

21. A digital receiver according to claim 1, wherein the sensing means is arranged to track the envelope of the demodulated signal by making the following determinations:
if xₙ<xₙ₋₁>xₙ₋₂ and xₙ₋₁>Min+threshold and xₙ₋₁<MAX, And if xₙ₋₁>Max or xₙ₋₁>dcₙ₋₁, then Max=xₙ₋₁
if xₙ>xₙ₋₁<xₙ₋₂ and xₙ₋₁<Max−threshold and xₙ₋₁>−MAX, And if xₙ₋₁<Min or xₙ₋₁<dcₙ₋₁, then Min=xₙ₋₁
where, xₙ,xₙ₋₁,xₙ₋₂ are samples at time n, at time n-1 and at time n-2 of the first input signal, respectively, dcₙ₋₁ is low frequency component of the envelope of the demodulated signal at time n-1, Max and Min are the envelope signal which represent negative and positive peaks of the envelope of the demodulated signal, and threshold and MAX are preset constants.

22. A digital receiver according to claim 12, wherein the threshold and MAX are proportional to a sampling duration, a modulation index or amplitude of the demodulated signal.

23. A digital receiver according to claim 12, wherein the filter is arranged to calculate the frequency component of the envelope signal of the form:
$$d {c}_{n} = ( 1 - {α}_{n} ) d {c}_{n - 1} + \frac{{α}_{n}}{2} ( Max + Min )$$
where, dcₙ is a frequency component of the envelope signal at time n, dcₙ₋₁ is the frequency component of the envelope signal at time n-1, αₙ is the filter coefficient at time n.

24. A digital receiver, comprising:
a frequency converter arranged to convert a received signal into baseband signals;
delay units arranged to delay the baseband signals to provide delayed signals;
normalizing means arranged to truncate the baseband signals and the delayed signals to a predetermined length and provide normalized signals;
a demodulator arranged to demodulate the normalized signals and provide a demodulated signal; and
a filter arranged to filter the demodulated signal to provide a filtered signal and wherein the filter is arranged to have a bandwidth which decreases as a function of time.
